(19) United States
(12) Patent Application Publication
(10) Pub. No.: US 2015/0349031 A1
(43) Pub. Date: Dec. 3, 2015

(54) 3-D Displaying Panel Having Depth-Of-Field Effect And Displaying Method Thereof

(71) Applicant: Shenzhen China Star Optoelectronics Technology Co. Ltd., Shenzhen, Guangdong (CN)

(72) Inventor: Xiangyang XU, Shenzhen, Guangdong (CN)

(73) Assignee: Shenzhen China Star Optoelectronics Technology Co. Ltd., Shenzhen, Guangdong (CN)

(21) Appl. No.: 14/241,074

(22) PCT Filed: Jan. 3, 2014
(86) PCT No.: PCT/CN2014/070050

§ 371 Date: Feb. 25, 2014

(30) Foreign Application Priority Data
Dec. 16, 2013 (CN) 201310694951.9

(51) Int. Cl. H01L 27/32; G09G 3/32; G09G 3/00

(52) U.S. Cl. CPC H01L 27/326; G09G 3/003; G09G 3/3225

(57) ABSTRACT

The present invention provides a 3-D display panel having depth-of-field effect, and which includes a substrate (12) and thin-film-transistor array (14) formed on the substrate (12), a first organic light emitting layer (16) formed onto the thin-film-transistor array (14), an insulative layer (17) disposed onto the thin-film-transistor array (14) and the first organic light-emitting layer (16), and a second organic light-emitting layer (18) formed onto the insulative layer (17), an cathode layer (19) disposed onto the insulative layer (17) and the second light-emitting layer (18), wherein the first light-emitting layer (16) and the second light-emitting layer (18) are offset from each other, and wherein the first organic light-emitting layer (16) displays a screen of near view, and the second organic light-emitting layer (18) displays a screen of father view such that the near view and the father view are separately to display the 3-D effects.

### FIELD OF THE INVENTION

The present invention relates to a field of 3-D displaying technology, and more particularly, to a 3-D displaying panel having depth-of-field effect and a displaying method thereof.

### DESCRIPTION OF PRIOR ART

3D display technology has become the main stream of the display field. With the 3D display technology, a picture or image can be made to become a three-dimensional lifelike images which are no longer confined to the plane of the screen, as if the images walk out of the screen, thereby providing the audience an immersive feeling. Currently, the 3D display technology is generally used to implement the principle of binocular disparity, i.e. two parallax images (i.e., left and right parallax images) displayed on a two-dimensional display. Then, with a technique by using the viewer's left and right eyes, respectively, the view can see the 3-D effect by seeing the left or right parallax images on a two-dimensional display each time.

3D display technology can be divided into two categories, glass-type and naked eye type. There are two types of naked eye 3-D displaying technology: light barrier type technology and cylindrical lens technology.

Light barrier 3D display technology is to use a switch LCD screen, the polarizing film and high polymer liquid crystal molecules layer. By using a polymer liquid crystal layer and the polarizing film to produce a series of the vertical stripes. Those stripes have a width of several tens of micrometers. The light beams pass through those thin vertical stripes will create a gate pattern, called “parallax barrier.” And the light barrier type 3D display technology is exactly use of a parallax barrier display when implemented between the panel and LCD backlight module. In the three-dimensional display mode, when the image displayed on the screen should only be seen by the left eye is displayed on the LCD screen, opaque stripes would block right eye; with the same reason, when the image displayed on the screen should only be seen by the right eye is displayed on the LCD screen, opaque stripes would block left eye. By separation of the images to be seen by left eye and right eye, such as shown in FIG. 1, the viewer sees the 3-D images on the screen. it should be seen by the right eye image is displayed on the LCD screen, opaque stripes would block the left eye, left eye and right eye by a visual screen to separate (FIG. 1), so that outlook who see the 3D image. This technology is relatively low cost, but the low screen brightness. The cost is comparable low, while the brightness of the screen is also compromised.

Lenticular lens technology is also known as micro-cylinder lens 3D display technologies. The liquid crystal panel is located on the image plane in the focal plane of the lens, so that the pixels are divided into several sub-columns in each image pixel below the lens. Then, the lenses can be used to project the image of pixel toward different directions. Accordingly, when the projected pixels are viewed from a different angle, different sub-pixels are seen and a 3D effect is therefore created. This 3D display technology shows better results, the brightness is not affected, but its manufacturing process is not compatible to the manufacturing technology of LCD, the need to invest in new equipment and production lines. Additional equipment and production lines need to be included if this technology is to be included in the LCD.

The organic light emitting display (Organic Light-Emitting Display, OLED) is a light emitting device in which the organic semiconductor material and an emissive electroluminescent layer which emits light in response to an electric current or electric field. The OLED can be categorized into the following: passive matrix organic light emitting diode display (Passive-matrix organic light emitting diode, PMOLED) and active-matrix organic light emitting diode display (Active-matrix organic light emitting diode, AMOLED). Now, please refer to FIG. 2, the configuration of the active matrix organic light emitting diode panel generally includes a substrate 102, a thin film transistor array 104 formed on the substrate 102, an organic light emitting layer 106 formed on the thin film transistor array 104, and a cathode layer 108 formed on the organic light emitting layer 106. Refer to FIG. 3, the working principle of an active matrix organic light emitting diode panel is by utilizing a transparent electrodes (e.g., indium tin oxide ITO electrode) 202 and the metal electrode 204 as an anode and a cathode, respectively. When the organic light emitting device is driven at a constant voltage, electrons 302 and electron holes 304 are injected from the cathode 202 and the anode 204 into the electron transport layer 206 and the electron hole transport layer 208. The electrons 302 and the electron holes 304 then respectively migrate and eventually encounter at the light emitting layer 209 from the electron transport layer 206 and the electron hole transport layer 208, and causing the emissive electroluminescent layer be excited to emit visible light 306. The visible light 306 can be seen from the side of the transparent electrode 202, and the metal electrode 204 is also served as a reflective layer.

In terms of graphics performance, active-matrix organic light emitting diode display features faster response, higher contrast, wider viewing angle. These features are the born-with characteristics of the active matrix organic light emitting diode display, and which is inherently better than the thin-film transistor liquid crystal display (Thin Film Transistor Liquid crystal Display, TFT LCD). Another feature of the active matrix organic light emitting diode display is that it is a self-luminous, no need the use of the backlight module. As a result, the active matrix organic light emitting diode display can be made thinner and more power saving. Without the use of the backlight module, the active matrix organic light emitting diode display can save the cost of the backlight module, which is about 3-4 percent of the thin-film transistor liquid crystal display.

### SUMMARY OF THE INVENTION

It is an object of the present invention to provide a 3-D displaying panel having depth-of-field effect, and the 3-D displaying panel can readily resolve the 3-D naked eye displaying technical problems encountered by the thin-film-transistor liquid crystal display device. And based on the features of active illumination of the active matrix organic light-emitting diode display panel in which the light, it features a cost-effective, high brightness, quick responding time, high contrast, and larger view angles. In addition, it has 3-D depth-of-field effect so as to present a 3-D effect more closely to the view seen from our naked eye.

It is another object of the present invention to provide a 3-D displaying panel and a displaying method thereof. By utilizing first and second organic light emitting layers located at different levels or heights to display a near view and a father view, respectively, thereby realizing the 3-D display by the method of respectively displaying the near view and the father view. It features cost-effective, high brightness, quick responding time, high contrast, and larger view angles. In addition, it has 3-D depth-of-field effect so as to present a 3-D effect more closely to the view seen from our naked eye.

In order to achieve the object set forth, the present invention provides a 3-D display panel having depth-of-field effect and which includes a substrate and thin-film-transistor array formed on the substrate, a first organic light emitting layer formed onto the thin-film-transistor array, an insulative layer disposed onto the thin-film-transistor array and the first organic light-emitting layer, and a second organic light-emitting layer formed onto the insulative layer, an cathode layer disposed onto the insulative layer and the second light-emitting layer, wherein the first light-emitting layer and the second light-emitting layer are offset from each other, and wherein the first organic light-emitting layer displays a screen of near view, and the second organic light-emitting layer displays a screen of father view such that the near view and the father view are separately to display the 3-D effect.

Wherein the first organic light-emitting layer includes a plurality of first organic modules, and the second organic light-emitting layer includes a plurality of second organic modules, wherein the first and second organic modules are offset from each other across a displaying area of the 3-D display panel.

Wherein further includes a barrier disposed on a side of the substrate distant to the thin-film-transistor array to provide a grating effect.

Wherein the insulative layer is composed with organic insulative layer, and the cathode is configured by metallic material.

Wherein the 3-D display panel is a naked-eye 3-D display panel.

Wherein the 3-D displaying panel is an active matrix light-emitting diode panel.

The present invention further provides a 3-D display panel having depth-of-field effect, and which includes a substrate and thin-film-transistor array formed on the substrate, a first organic light emitting layer formed onto the thin-film-transistor array, an insulative layer disposed onto the thin-film-transistor array and the first organic light-emitting layer, and a second organic light-emitting layer formed onto the insulative layer, an cathode layer disposed onto the insulative layer and the second light-emitting layer, wherein the first light-emitting layer and the second light-emitting layer are offset from each other, and wherein the first organic light-emitting layer displays a screen of near view, and the second organic light-emitting layer displays a screen of father view such that the near view and the father view are separately to display the 3-D effect; and

wherein the first organic light-emitting layer includes a plurality of first organic modules, and the second organic light-emitting layer includes a plurality of second organic modules, wherein the first and second organic modules are offset from each other across a displaying area of the 3-D display panel.

Wherein further includes a barrier disposed on a side of the substrate distant to the thin-film-transistor array to provide a grating effect.

Wherein the insulative layer is composed with organic insulative layer, and the cathode is configured by metallic material.

Wherein the 3-D display panel is a naked-eye 3-D display panel.

Wherein the 3-D displaying panel is an active matrix light-emitting diode panel.

The present invention further provides a method for displaying a 3-D displaying panel, including the steps of:

step 1, providing a 3-D displaying panel having first and second organic light-emitting layers arranged in different heights, wherein the first and second organic light-emitting layers are offset from each other; and

step 2, driving the 3-D displaying panel to have the first organic light-emitting layer to display near view, and the second organic light-emitting layer to display father view so as to differentiate the near view and the father view to realize the 3-D display.

Wherein the 3-D displaying panel includes a substrate, a thin-film-transistor array, an insulative layer, an cathode layer and a barrier, wherein the thin-film-transistor array is formed onto the substrate, the first organic light-emitting layer is disposed onto the thin-film-transistor, the insulative layer is disposed onto the thin-film-transistor array and the first organic light-emitting layer, wherein the second organic light-emitting layer is formed onto the insulative layer, and the cathode is formed onto the insulative layer and the second organic light-emitting layer, the barrier is disposed on a side of the substrate distant to the thin-film-transistor array provide a grating effect.

Wherein the first organic light-emitting layer includes a plurality of first organic modules, and the second organic light-emitting layer includes a plurality of second organic modules, wherein the first and second organic modules are offset from each other across a displaying area of the 3-D display panel.

Wherein the insulative layer is composed with organic insulative layer, and the cathode is configured by metallic material, wherein the 3-D display panel is a naked-eye 3-D display panel, wherein the 3-D displaying panel is a naked eye displaying panel with an active matrix organic light-emitting diodes.

The present invention can be concluded with the following advantages. With the 3-D displaying panel having the depth-of-field effect and the method for displaying it provided by the present invention, by utilizing the first and second organic light-emitting layers arranged in different height to display the near view and the father view, the 3-D display can be readily displayed with the separation of the near view and the father view. Accordingly, the 3-D naked eye displaying problem encountered by the thin-film-transistor liquid crystal display can be readily resolved. In addition, it is based on the light-emitting characteristics of the displaying panel made with the active matrix organic light-emitting diodes. It features cost-effective, high brightness, quick responding time, high contrast, and larger view angles. In addition, it has 3-D depth-of-field effect so as to present a 3-D effect more closely to the view seen from our naked eye.

In order to better illustrate the characteristic and technologies of the present invention, detailed description to the preferred embodiments is given along with the accompanied drawings. However, it should be noted that the accompanied is merely for reference and illustration, while should not be treated as a limitation to the present invention.

### BRIEF DESCRIPTION OF DRAWINGS

The technologies and its intended purposes and advantages will become more evident with the detailed description to the embodiments with referring to the attached drawings. In which

FIG. 1 is a working principle of the prior art 3-D displaying technology in which a barrier is implemented;

FIG. 2 is a configurational and illustrational view of a prior art displaying panel having active matrix organic light-emitting diodes;

FIG. 3 is an illustration of the working principle of the prior art active matrix organic light-emitting diodes;

FIG. 4 is a configurational and illustrational view of a 3-D displaying panel having depth-of-field effect made in accordance with the present invention;

FIG. 5 is an illustration of working principle of a 3-D displaying panel having depth-of-field effect made in accordance with the present invention; and

FIG. 6 is a flow chart diagram of the displaying method of the 3-D displaying panel made in accordance with the present invention.

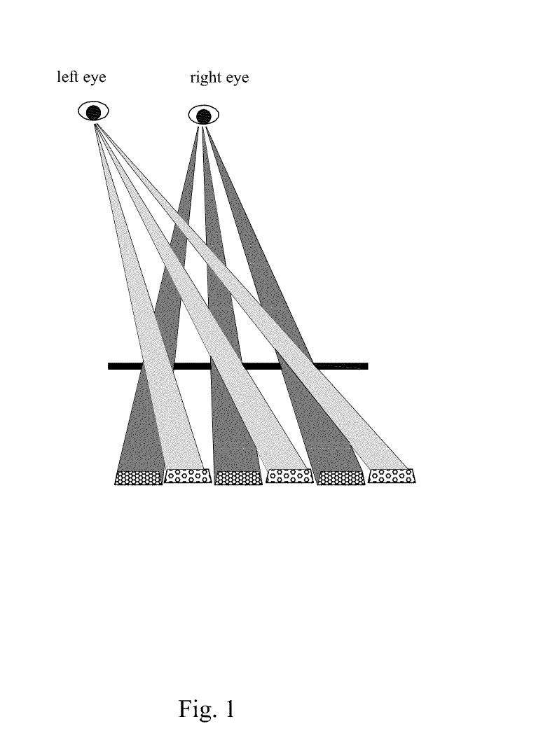

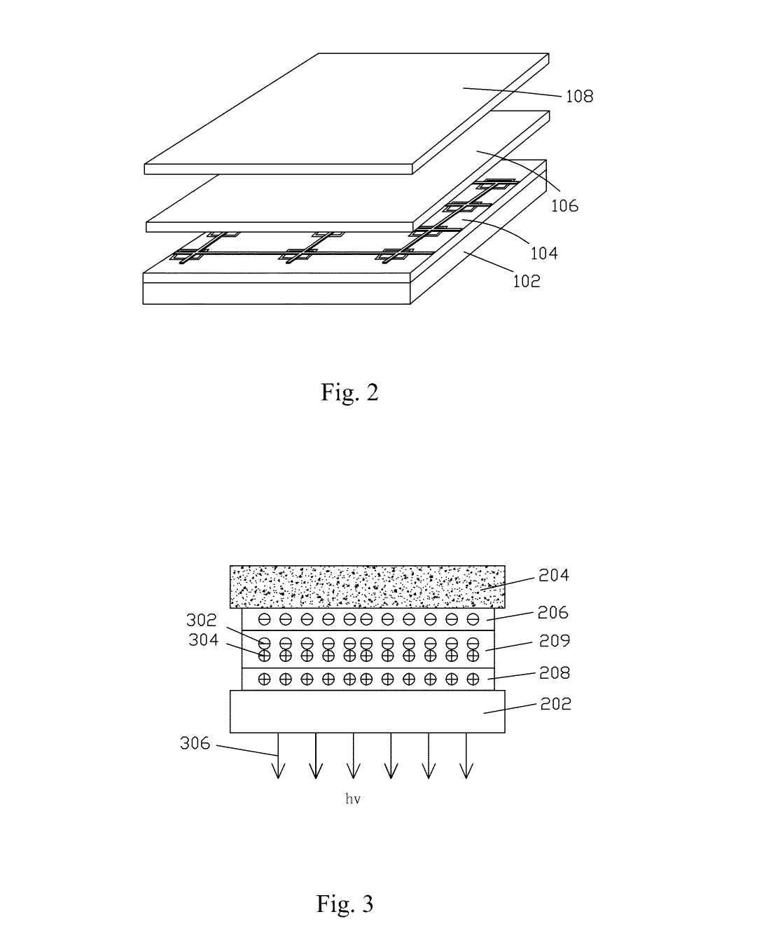

### DETAILED DESCRIPTION OF PREFERRED EMBODIMENTS

In order to further elaborate the manner and the results achieved by the present invention, detailed description of preferred embodiments will be given along with the accompanied drawings.

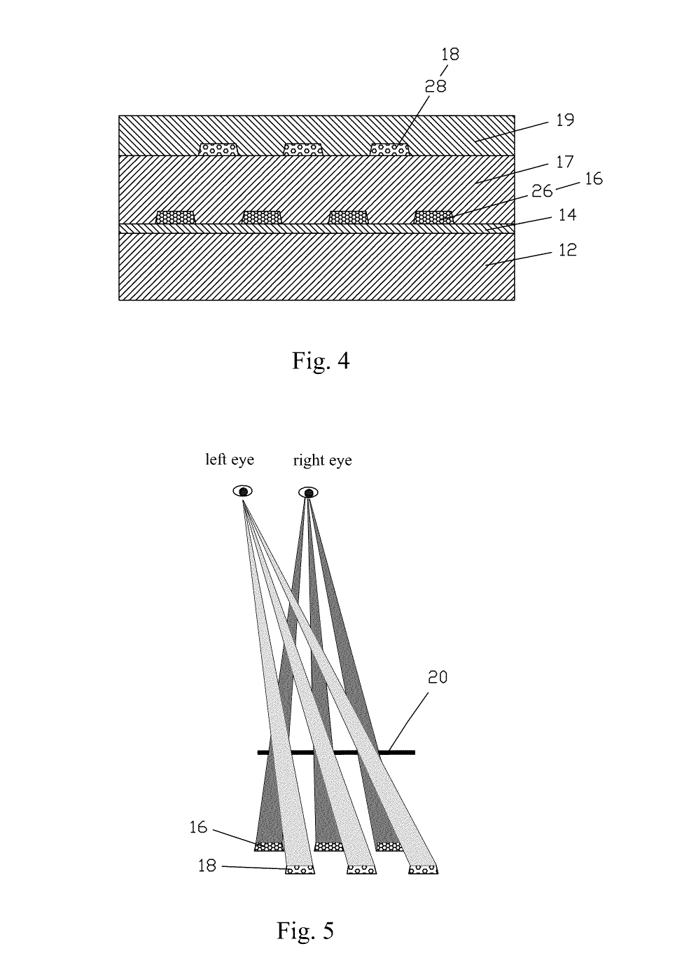

Referring to FIGS. 4 and 5, the present invention provides a 3-D display panel having depth-of-field effect, and which includes a substrate 12 and thin-film-transistor array 14 formed on the substrate 12, a first organic light emitting layer 16 formed onto the thin-film-transistor array 14, an insulative layer 17 disposed onto the thin-film-transistor array 14 and the first organic light-emitting layer 16, and a second organic light-emitting layer 18 formed onto the insulative layer 17, an cathode layer 19 disposed onto the insulative layer 17 and the second light-emitting layer 18, wherein the first light-emitting layer 16 and the second light-emitting layer 18 are offset from each other, and wherein the first organic light-emitting layer 16 displays a screen of near view, and the second organic light-emitting layer 18 displays a screen of father view such that the near view and the father view are separately to display the 3-D effect. By the provision of the forgoing technological solution, the prior art issues encountered by those naked eye 3-D technologies of those two types of LCD are properly resolved.

Wherein the first organic light-emitting layer 16 includes a plurality of first organic modules 26, and the second organic light-emitting layer 18 includes a plurality of second organic module 28, wherein the first and second organic modules 26, 28 are offset from each other across a displaying area of the 3-D display panel.

Wherein the displaying method for 3-D display panel further includes a barrier 20 disposed on a side of the substrate 12 distant to the thin-film-transistor array 14 to provide a grating effect. The barrier 20 is disposed on a light-exiting surface of the 3-D displaying panel.

The insulative layer 17 is used to insulatively separate the first and second organic light-emitting layers 16 and 18 in three dimensions. The thickness of it can be set according to actual requirements. Preferably, the insulative layer is made from organic insulative material. The cathode 19 is made from metallic material, and which can be selected from metallic material generally available to the market so as to reduce the costs.

The substrate 12 is an insulative substrate, preferably it is made from transparent glass material.

The 3-D displaying panel is a naked eye displaying panel with an active matrix organic light-emitting diodes. It features cost-effective, high brightness, quick responding time, high contrast, and larger view angles. In addition, it has 3-D depth-of-field effect so as to present a 3-D effect more closely to the view seen from our naked eye.

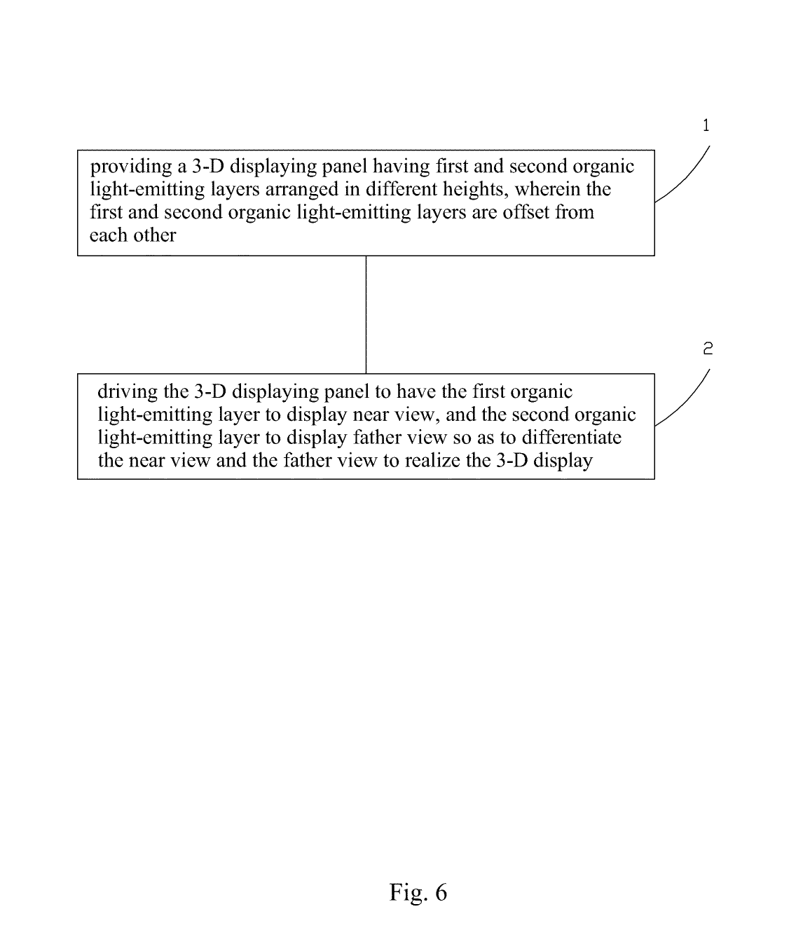

Referring to FIG. 6 along with FIGS. 4 and 5, the present invention further provides a method for displaying a 3-D displaying panel, including the steps of:

Step 1, providing a 3-D displaying panel having first and second organic light-emitting layers 16, 18 arranged in different heights, wherein the first and second organic light-emitting layers 16, 18 are offset from each other; and

Wherein the 3-D displaying panel includes a substrate 12, a thin-film-transistor array 14, an insulative layer 17, an cathode layer 19 and a barrier 20, wherein the thin-film-transistor array 14 is formed onto the substrate 12, the first organic light-emitting layer 16 is disposed onto the thin-film-transistor 14, the insulative layer 17 is disposed onto the thin-film-transistor array 14 and the first organic light-emitting layer 16, wherein the second organic light-emitting layer 18 is formed onto the insulative layer 17, and the cathode 19 is formed onto the insulative layer 19 and the second organic light-emitting layer 18, the barrier 20 is disposed on a side of the substrate 12 distant to the thin-film-transistor array 14 to provide a grating effect. The barrier 20 is disposed on a light-exiting surface of the 3-D displaying panel.

Wherein the first organic light-emitting layer 16 includes a plurality of first organic modules 26, and the second organic light-emitting layer 18 includes a plurality of second organic modules 28, wherein the first and second organic modules 26, 28 are offset from each other across a displaying area of the 3-D display panel.

The insulative layer 17 is used to insulatively separate the first and second organic light-emitting layers 16 and 18 in three dimensions. The thickness of it can be set according to actual requirements. Preferably, the insulative layer is made from organic insulative material. The cathode 19 is made from metallic material, and which can be selected from metallic material generally available to the market so as to reduce the costs.

The substrate 12 is an insulative substrate, preferably it is made from transparent glass material.

Step 2, driving the 3-D displaying panel to have the first organic light-emitting layer 16 to display near view, and the second organic light-emitting layer 18 to display father view so as to differentiate the near view and the father view to realize the 3-D display.

With the provision of the method described to implement the naked eye 3-D display, the problems encountered by those two types of prior art naked eye 3-D liquid crystal display can be readily resolved. In addition, the method is quite simple.

The 3-D displaying panel is a naked eye displaying panel with an active matrix organic light-emitting diodes. It features cost-effective, high brightness, quick responding time, high contrast, and larger view angles. In addition, it has 3-D depth-of-field effect so as to present a 3-D effect more closely to the view seen from our naked eye.

In conclusion, with the 3-D displaying panel having the depth-of-field effect and the method for displaying it provided by the present invention, by utilizing the first and second organic light-emitting layers arranged in different height to display the near view and the father view, the 3-D display can be readily displayed with the separation of the near view and the father view. Accordingly, the 3-D naked eye displaying problem encountered by the thin-film-transistor liquid crystal display can be readily resolved. In addition, it is based on the light-emitting characteristics of the displaying panel made with the active matrix organic light-emitting diodes. It features cost-effective, high brightness, quick responding time, high contrast, and larger view angles. In addition, it has 3-D depth-of-field effect so as to present a 3-D effect more closely to the view seen from our naked eye.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

1. A 3-D display panel having depth-of-field effect, including a substrate and thin-film-transistor array formed on the substrate, a first organic light emitting layer formed onto the thin-film-transistor array, an insulative layer disposed onto the thin-film-transistor array and the first organic light-emitting layer, and a second organic light-emitting layer formed onto the insulative layer, an cathode layer disposed onto the insulative layer and the second light-emitting layer, wherein the first light-emitting layer and the second light-emitting layer are offset from each other, and wherein the first organic light-emitting layer displays a screen of near view, and the second organic light-emitting layer displays a screen of father view such that the near view and the father view are separately to display the 3-D effect.

2. The 3-D display panel having depth-of-field effect as recited in claim 1, wherein the first organic light-emitting layer includes a plurality of first organic modules, and the second organic light-emitting layer includes a plurality of second organic modules, wherein the first and second organic modules are offset from each other across a displaying area of the 3-D display panel.

3. The 3-D display panel having depth-of-field effect as recited in claim 1, wherein further includes a barrier disposed on a side of the substrate distant to the thin-film-transistor array to provide a grating effect.

4. The 3-D display panel having depth-of-field effect as recited in claim 1, wherein the insulative layer is composed with organic insulative layer, and the cathode is configured by metallic material.

5. The 3-D display panel having depth-of-field effect as recited in claim 1, wherein the 3-D display panel is a naked eye displaying panel.

6. The 3-D display panel having depth-of-field effect as recited in claim 5, wherein the 3-D displaying panel is an active matrix light-emitting diode panel.

7. A 3-D display panel having depth-of-field effect, including a substrate and thin-film-transistor array formed on the substrate, a first organic light emitting layer formed onto the thin-film-transistor array, an insulative layer disposed onto the thin-film-transistor array and the first organic light-emitting layer, and a second organic light-emitting layer formed onto the insulative layer, an cathode layer disposed onto the insulative layer and the second light-emitting layer, wherein the first light-emitting layer and the second light-emitting layer are offset from each other, and wherein the first organic light-emitting layer displays a screen of near view, and the second organic light-emitting layer displays a screen of father view such that the near view and the father view are separately to display the 3-D effect; and
wherein the first organic light-emitting layer includes a plurality of first organic modules, and the second organic light-emitting layer includes a plurality of second organic modules, wherein the first and second organic modules are offset from each other across a displaying area of the 3-D display panel.

8. The 3-D display panel having depth-of-field effect as recited in claim 7, wherein further includes a barrier disposed on a side of the substrate distant to the thin-film-transistor array to provide a grating effect.

9. The 3-D display panel having depth-of-field effect as recited in claim 7, wherein the insulative layer is composed with organic insulative layer, and the cathode is configured by metallic material.

10. The 3-D display panel having depth-of-field effect as recited in claim 7, wherein the 3-D display panel is a naked eye displaying panel.

11. The 3-D display panel having depth-of-field effect as recited in claim 10, wherein the 3-D displaying panel is an active matrix light-emitting diode panel.

12. A method for displaying a 3-D displaying panel, including the steps of:
step 1, providing a 3-D displaying panel having first and second organic light-emitting layers arranged in different heights, wherein the first and second organic light-emitting layers are offset from each other; and
step 2, driving the 3-D displaying panel to have the first organic light-emitting layer to display near view, and the second organic light-emitting layer to display father view so as to differentiate the near view and the father view to realize the 3-D display.

13. The displaying method for 3-D display panel as recited in claim 12, wherein the 3-D displaying panel includes a substrate, a thin-film-transistor array, an insulative layer, an cathode layer and a barrier, wherein the thin-film-transistor array is formed onto the substrate, the first organic light-emitting layer is disposed onto the thin-film-transistor, the insulative layer is disposed onto the thin-film-transistor array and the first organic light-emitting layer, wherein the second organic light-emitting layer is formed onto the insulative layer, and the cathode is formed onto the insulative layer and the second organic light-emitting layer, the barrier is disposed on a side of the substrate distant to the thin-film-transistor array provide a grating effect.

14. The displaying method for 3-D display panel as recited in claim 13, wherein the first organic light-emitting layer includes a plurality of first organic modules, and the second organic light-emitting layer includes a plurality of second organic modules, wherein the first and second organic modules are offset from each other across a displaying area of the 3-D display panel.

15. The displaying method for 3-D display panel as recited in claim 13, wherein the insulative layer is composed with organic insulative layer, and the cathode is configured by metallic material, wherein the 3-D display panel is a naked-eye 3-D display panel, wherein the 3-D displaying panel is an active matrix light-emitting diode panel.
